(19) United States
(12) Patent Application Publication
(10) Pub. No.: US 2026/0129750 A1
(43) Pub. Date: May 7, 2026

(54) FLEXIBLE PRINTED CIRCUIT BOARD FOR SMALL BENDING-RADIUS APPLICATIONS

(71) Applicant: NVIDIA CORPORATION, Santa Clara, CA (US)

(72) Inventors: Biao HU, San Jose, CA (US); Yunseok KIM, Pleasanton, CA (US); Shuang XU, San Jose, CA (US); Jungho NA, Milpitas, CA (US); Xiang SUN, Los Gatos, CA (US)

(21) Appl. No.: 18/937,973

(22) Filed: Nov. 5, 2024

(51) Int. Cl. H05K 1/02; H05K 1/03; H05K 1/14

(52) U.S. Cl. CPC H05K 1/0277; H05K 1/0366; H05K 1/14; H05K 2201/015; H05K 2201/0275

(57) ABSTRACT

According to various embodiments, a flexible printed circuit board includes: a first flexible dielectric layer that includes reinforcing fibers; a second flexible dielectric layer that includes no reinforcing fibers; and a first conductive layer that is disposed between the first dielectric layer and the second dielectric layer and contacts the first dielectric layer and the second dielectric layer.

### BACKGROUND

### Field of the Various Embodiments

The various embodiments relate generally to computer systems and computer hardware architecture and, more specifically, to a flexible printed circuit board for small bending-radius applications.

### Description of the Related Art

Many types of computers are designed to incorporate one or more expansion cards that provide the computer with additional capabilities, such as enhanced video or gaming performance, accelerated video capture, the ability to connect to a network, and/or the ability to connect to a musical instrument, to name a few. An expansion card, which also is referred to as an adapter card, an add-on card, or an expansion board, is a card-based processing subsystem that typically includes a printed circuit board (PCB) that is adapted to connect to an expansion slot on the motherboard of a given computer.

Some card-based processing subsystems include a secondary PCB that serves as an input/output (I/O) interface. These secondary PCBs normally have one or more I/O connectors mounted thereon. For example, graphics cards typically include various video interface connectors that are mounted on a secondary PCB, while network interface cards typically include a plurality of network connection ports that are mounted on a secondary PCB. In modern card-based processing subsystems, routing the signals between the secondary PCB and the main PCB can be quite challenging due to the large number of electrical connections (e.g., I/O signals, power connections, and ground connections) that oftentimes are required between the main PCB and the secondary PCB. In addition, the many electrical connections between the main PCB and the secondary PCB have to be routed within a highly confined space, which further complicates the routing problem.

Traditionally, multi-conductor cables and wire harnesses have been employed to route large numbers of signals and/or power connections between two PCBs in computing devices, such as desktop computers. In many applications, these cables and wire harnesses can operate with sufficiently low insertion losses and parasitic impedances to transmit the high-frequency signals typically employed in modern computing devices. However, multi-conductor cables are oftentimes too bulky for use in many compact computing devices, including laptop computers, smart phones, and card-based processing subsystems. Instead, large numbers of conductors have to be routed through the confined spaces within these more compact computing devices using flexible PCBs. Flexible PCBs can include multiple layers of miniaturized and insulated conductors and, therefore, are usually more compact than multi-conductor cables or wire harnesses.

While flexible PCBs are more flexible than conventional rigid PCBs, the minimum bend radius available to a flexible PCB remains somewhat limited. As a result, the small radius bending that sometimes occur when routing electrical connections within the housing of a compact computing device can exceed the minimum bend radius of the flexible PCB. Such over-bending of a flexible PCB can compromise the continuity of conductors within a bend and cause dielectric cracking on the outer radius of the bend and dielectric wrinkling or separation on the inner radius of the bend.

As the foregoing illustrates, what is needed in the art are more effective techniques for routing electrical connections within compact computing devices.

### SUMMARY

According to various embodiments, a flexible printed circuit board includes: a first flexible dielectric layer that includes reinforcing fibers; a second flexible dielectric layer that includes no reinforcing fibers; and a first conductive layer that is disposed between the first dielectric layer and the second dielectric layer and contacts the first dielectric layer and the second dielectric layer.

At least one technical advantage of the disclosed design relative to the prior art is that the disclosed design enables electrical connections to be routed through one or more small-radius turns within a compact computing device without any dielectric cracking or dielectric wrinkling or separation and more effectively than what can be achieved with prior art designs. A further technical advantage is that the disclosed design enables electrical connections to be routed within the compact computing device with low insertion losses and low parasitic impedances, which allows the electrical connections of the disclosed design to transmit high-frequency signals. These technical advantages provide one or more technological advancements over prior art approaches and designs.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a computer system configured to implement one or more aspects of the various embodiments.

FIG. 2 is another illustration of the computer system of FIG. 1, according to various embodiments.

FIGS. 3A and 3B are more detailed illustrations of the card-based processing subsystem of FIG. 2, according to various embodiments.

FIG. 4 is a perspective view of a flexible PCB, the first rigid PCB, and the second rigid PCB of FIGS. 3A and 3B installed within a card-based processing subsystem, according to various embodiments.

FIG. 5 is a plan view of the flexible PCB of FIG. 4 in an unbent state, prior to installation within a card-based processing subsystem, according to various embodiments.

FIG. 6 is a conceptual illustration of a layer stack-up for the flexible PCB of FIG. 4, according to various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skilled in the art that the inventive concepts may be practiced without one or more of these specific details.

### Introduction

According to various embodiments, a flexible printed circuit board (PCB) is capable of a tighter bend radius than conventional flexible PCBs known in the art. In the embodiments, the flexible PCB includes one or more inner dielectric layers that are disposed within the flexible PCB and one or more outer dielectric layers that enclose the inner dielectric layer(s). For example, in some embodiments, the inner dielectric layer(s) are disposed between at least one outer dielectric layer coupled to a top surface of the inner dielectric layer(s) and at least one outer dielectric layer coupled to a bottom surface of the inner dielectric layer(s). Further, in the embodiments, the outer dielectric layers include a synthetic polymer material and reinforcing fibers, while the inner dielectric layer(s) include a synthetic polymer material with no reinforcing fibers.

### System Overview

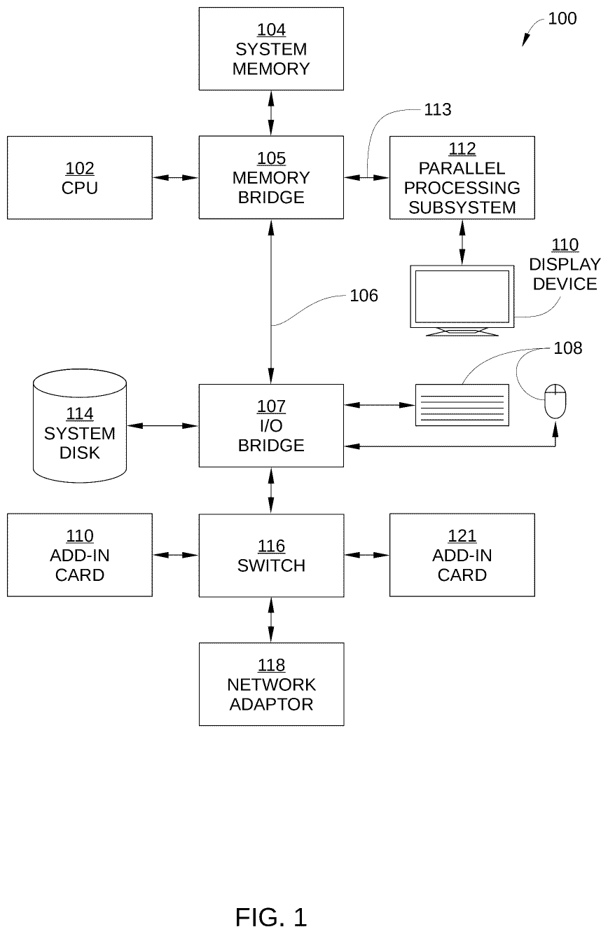

FIG. 1 is a conceptual illustration of a computer system 100 configured to implement one or more aspects of the various embodiments. As shown, system 100 includes a central processing unit (CPU) 102 and a system memory 104 communicating via a bus path that may include a memory bridge 105. CPU 102 includes one or more processing cores, and, in operation, CPU 102 is the master processor of system 100, controlling and coordinating operations of other system components. System memory 104 stores software applications and data for use by CPU 102. CPU 102 runs software applications and optionally an operating system. Memory bridge 105, which may be, e.g., a Northbridge chip, is connected via a bus or other communication path (e.g., a HyperTransport link) to an I/O (input/output) bridge 107. I/O bridge 107, which may be, e.g., a Southbridge chip, receives user input from one or more user input devices 108 (e.g., keyboard, mouse, joystick, digitizer tablets, touch pads, touch screens, still or video cameras, motion sensors, and/or microphones) and forwards the input to CPU 102 via memory bridge 105.

A display processor 112 is coupled to memory bridge 105 via a bus or other communication path (e.g., a PCI Express, Accelerated Graphics Port, or HyperTransport link); in one embodiment display processor 112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 104.

Display processor 112 periodically delivers pixels to a display device 110 (e.g., a screen or conventional CRT, plasma, OLED, SED or LCD based monitor or television). Additionally, display processor 112 may output pixels to film recorders adapted to reproduce computer generated images on photographic film. Display processor 112 can provide display device 110 with an analog or digital signal. In various embodiments, a graphical user interface is displayed to one or more users via display device 110, and the one or more users can input data into and receive visual output from the graphical user interface.

A system disk 114 is also connected to I/O bridge 107 and may be configured to store content and applications and data for use by CPU 102 and display processor 112. System disk 114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 116 provides connections between I/O bridge 107 and other components such as a network adapter 118 and various add-in cards 120 and 121. Network adapter 118 allows system 100 to communicate with other systems via an electronic communications network, and may include wired or wireless communication over local area networks and wide area networks such as the Internet.

Other components (not shown), including USB or other port connections, film recording devices, and the like, may also be connected to I/O bridge 107. For example, an audio processor may be used to generate analog or digital audio output from instructions and/or data provided by CPU 102, system memory 104, or system disk 114. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 112 is configured as a processing subsystem that incorporates circuitry optimized for graphics and video processing, including, for example, video output circuitry, and constitutes a graphics processing unit (GPU). In another embodiment, display processor 112 is configured as a processing subsystem that incorporates circuitry optimized for general purpose processing. In yet another embodiment, display processor 112 may be integrated with one or more other system elements, such as the memory bridge 105, CPU 102, and I/O bridge 107 to form a system on chip (SoC). In still further embodiments, display processor 112 is omitted and software executed by CPU 102 performs the functions of display processor 112.

Pixel data can be provided to display processor 112 directly from CPU 102. In some embodiments, instructions and/or data representing a scene are provided to a render farm or a set of server computers, each similar to system 100, via network adapter 118 or system disk 114. The render farm generates one or more rendered images of the scene using the provided instructions and/or data. These rendered images may be stored on computer-readable media in a digital format and optionally returned to system 100 for display. Similarly, stereo image pairs processed by display processor 112 may be output to other systems for display, stored in system disk 114, or stored on computer-readable media in a digital format.

Alternatively, CPU 102 provides display processor 112 with data and/or instructions defining the desired output images, from which display processor 112 generates the pixel data of one or more output images, including characterizing and/or adjusting the offset between stereo image pairs. The data and/or instructions defining the desired output images can be stored in system memory 104 or graphics memory within display processor 112. In an embodiment, display processor 112 includes 3D rendering capabilities for generating pixel data for output images from instructions and data defining the geometry, lighting shading, texturing, motion, and/or camera parameters for a scene. Display processor 112 can further include one or more programmable execution units capable of executing shader programs, tone mapping programs, and the like.

Further, in other embodiments, CPU 102 or display processor 112 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 102, display processor 112, or one or more other processing devices or any combination of these different processors.

CPU 102, render farm, and/or display processor 112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 100 may or may not include other elements shown in FIG. 1. System memory 104 and/or other memory units or devices in system 100 may include instructions that, when executed, cause a robot or robotic device represented by system 100 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 104 is connected to CPU 102 directly rather than through a bridge, and other devices communicate with system memory 104 via memory bridge 105 and CPU 102. In other alternative topologies display processor 112 is connected to I/O bridge 107 or directly to CPU 102, rather than to memory bridge 105. In still other embodiments, I/O bridge 107 and memory bridge 105 might be integrated into a single chip. The particular components shown herein are optional; for instance, any number of add-in cards or peripheral devices might be supported. In some embodiments, switch 116 is eliminated, and network adapter 118 and add-in cards 120, 121 connect directly to I/O bridge 107.

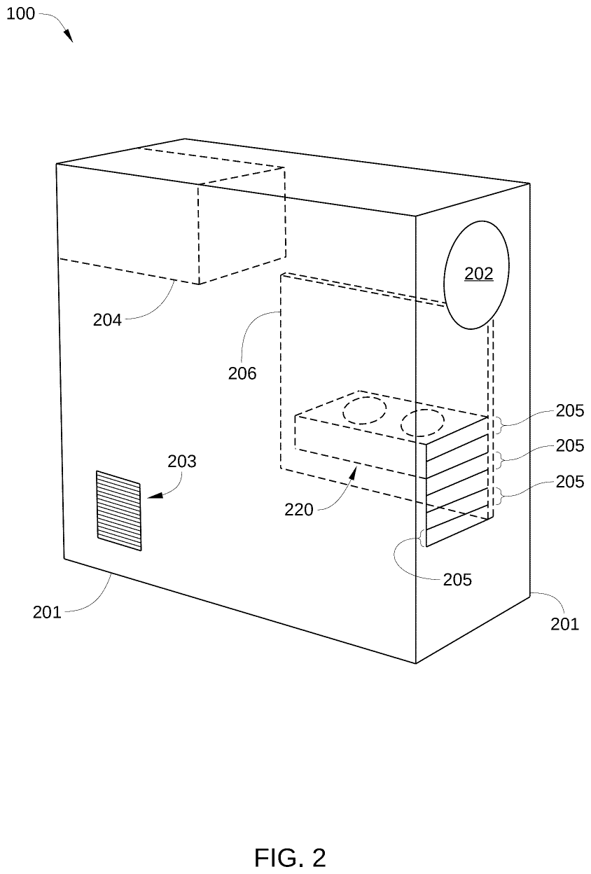

FIG. 2 is another illustration of computer system 100, according to various embodiments. As shown, computer system 100 includes a chassis 201 (also referred to as a “case” or “housing”) with one or more system cooling fans 202 mounted thereon and one or more cooling inlets 203 formed therein. Cooling fans 202 are configured to draw cooling air into chassis 201 to remove heat generated by various electronic components of computer system 100, for example via cooling inlets 203. In the embodiment illustrated in FIG. 2, computer system 100 further includes a power supply 204 mounted within chassis 201, a plurality of chassis expansion slots 205 that are typically located on a rear surface of chassis 201, and a motherboard 206 disposed within chassis 201.

Computer system 100 further includes various external connections (omitted for clarity) mounted on a rear and/or front surface of chassis 201, such as a power connection, Universal Serial Bus (USB) connections, an audio input jack, an audio output jack, one or more video output connections, and/or other connections. In some embodiments, one or more of such external connections are associated with motherboard 206 or an expansion card that is coupled to motherboard 206 and installed in a chassis expansion slot 205, such as a card-based processing subsystem 220.

In the embodiment illustrated in FIG. 2, motherboard 206 is configured with a central processing unit (CPU) and one or more card edge connectors, such as peripheral component interconnect express (PCIe) slots, that are each positioned to correspond to a different chassis expansion slot 205. For clarity, the CPU and card edge connectors of motherboard 206 are omitted in FIG. 2. Generally, computer system 100 is configured with one or more expansion cards or other card-based processing subsystems that are each mounted in a different chassis expansion slot 205 and communicatively coupled to motherboard 206 via a corresponding card edge connector. Examples of such card-based processing subsystems include card-based processing subsystems 220, such as wireless adapters, sound cards, graphics cards, network adapter 118, add-in cards 120, 121, or display processor 112 of FIG. 1, and/or the like. In the embodiment illustrated in FIG. 2, a single card-based processing subsystem 220 is coupled to motherboard 206, but in other embodiments, a plurality of card-based processing subsystems 220 may be coupled to motherboard 206.

In some embodiments, computer system 100 further includes one or more peripheral devices (not shown) that are communicatively coupled to motherboard 206 and/or a particular expansion card coupled to motherboard 206. For example, in some embodiments, computer system 100 includes one or more of a keyboard, mouse, joystick, digitizer tablet, touch pad, touch screen, display device, external hard drive, still or video cameras, motion sensors, microphones, and/or the like.

In the embodiment illustrated in FIG. 2, computer system 100 is depicted as a tower-configured desktop computer system. In other embodiments, computer system 100 can have any configuration that can include a card-based processing subsystem, such as a tower server computer system, a blade server computer system, a rack server computer system, a laptop computer, and/or the like.

### Card-Based Processing Subsystem

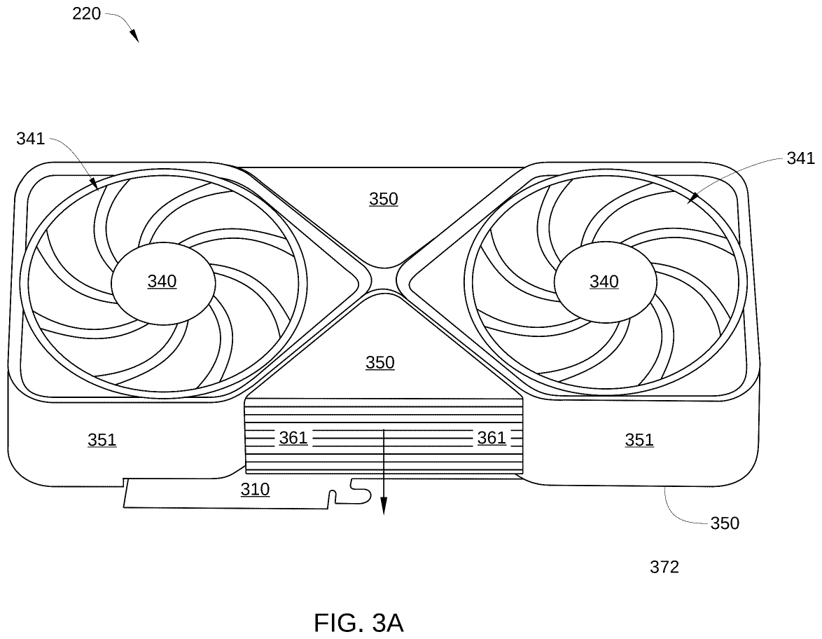

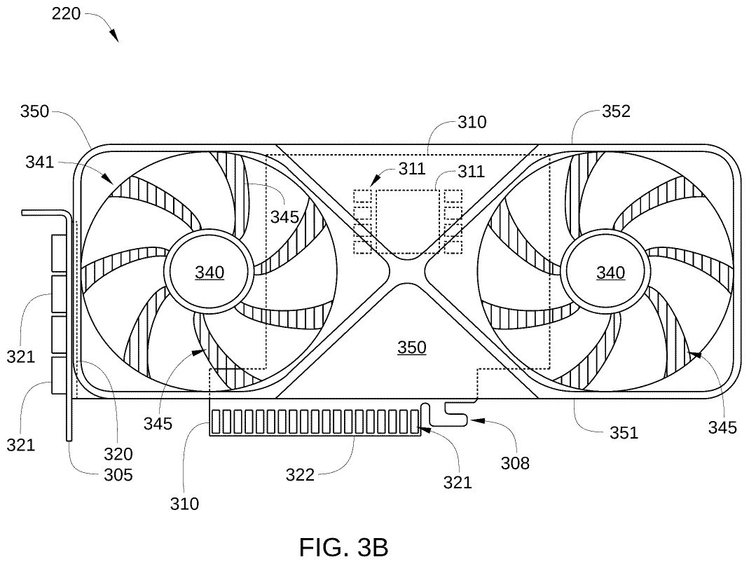

FIGS. 3A and 3B are more detailed illustrations of card-based processing subsystem 220, according to various embodiments. Specifically, FIG. 3A is a perspective view of card-based processing subsystem 220, according to various embodiments, and FIG. 3B is a top view of card-based processing subsystem 220, according to various embodiments. As shown, card-based processing subsystem 220 includes a first rigid printed circuit board (PCB) 310, a second rigid PCB 320 (shown with dashed lines in FIG. 3B), a heat exchanger (not visible) that includes a plurality of cooling fins 345, and one or more cooling fans 340 that are oriented to force cooling air (or any other suitable cooling fluid) through cooling fins 345. In the embodiment illustrated in FIGS. 3A and 3B, card-based processing subsystem 220 includes two cooling fans 340. In other embodiments, card-based processing subsystem 220 can include a single cooling fan 340 or three or more cooling fans 340.

In the embodiment illustrated in FIGS. 3A and 3B, card-based processing subsystem 220 further includes a housing 350 within which a first rigid PCB 310, a second rigid PCB 320, the heat exchanger and cooling fins 345, and cooling fans 340 are disposed. In such embodiments, housing 350 can facilitate positioning of cooling fans 340 relative to first rigid PCB 310, the heat exchanger, and cooling fins 345.

First rigid PCB 310 is partially visible in FIG. 3B below cooling fans 340, and has one or more integrated circuits (ICs) 311 (dashed lines) mounted thereon. For example, in embodiments in which card-based processing subsystem 220 is configured as a graphics card, the one or more ICs 311 include a graphics processing unit (GPU) and associated graphics memory chips. In some embodiments, first rigid PCB 310 has one or more ICs 311 mounted on a top surface that faces cooling fans 340. Alternatively or additionally, in some embodiments, first rigid PCB 310 has one or more ICs 311 mounted on a bottom surface that faces away from cooling fans 340. In embodiments in which card-based processing subsystem 220 is configured as a graphics card, the GPU is generally mounted on the above-described top surface of first rigid PCB 310 and is thermally coupled to a fan-based cooling system such as a heatsink (not shown in FIGS. 3A and 3B) and cooling fins 345, for example via thermal paste and/or the like.

In some embodiments, first rigid PCB 310 is configured to communicatively couple card-based processing subsystem 220 to a card edge connector, such as a PCIe slot included on motherboard 206 of computer system 100. To that end, first rigid PCB 310 includes a plurality of edge conductors 321 formed on an edge 322 of first rigid PCB 310. As shown, edge conductors 321 on edge 322 enable card-based processing subsystem 220 to be installed on motherboard 206.

In some embodiments, housing 350 has a form factor and electrical and mechanical connections (e.g., edge conductors 321, mechanical connection features 308, and backplate bracket 305) that enable the installation of card-based processing subsystem 220 onto a motherboard of a computer, such as motherboard 206 in FIG. 2. In such embodiments, housing 350 can have a form factor that occupies a region corresponding to an integral number of expansion slots on the motherboard.

The fan-based cooling system of card-based processing subsystem 220 is configured to transfer heat generated by ICs 311 and first rigid PCB 310 away from first rigid PCB 310, for example via a heatsink and cooling fins 345. Cooling air directed toward the heatsink and cooling fins 345 by cooling fans 340 then transports the heat out of card-based processing subsystem 220. In some embodiments, the heatsink includes cooling fins 345 that are thermally coupled to the one or more ICs 311 mounted on first rigid PCB 310. Further, in some embodiments, the fan-based cooling system includes a vapor chamber and/or heat pipes (not shown) that employ evaporative cooling to transfer heat from the one or more ICs 311 mounted on first rigid PCB 310 to cooling fins 345. Cooling fans 340 are disposed within housing 350 and are oriented to force air (or any other cooling fluid) through cooling fins 345 of the fan-based cooling system of card-based processing subsystem 220. In some embodiments, cooling fans 340 force a portion of the air or other cooling fluid out of one or more air outlets 361 that are disposed on a side wall 351 of housing 350 as shown in FIG. 3A.

Second rigid PCB 320 can operate as an input/output (I/O) interface for card-based processing subsystem 220, and therefore has one or more I/O connectors 321 mounted thereon. For example, in an embodiment in which card-based processing subsystem 220 is implemented as a graphics card, I/O connectors 321 can include one or more digital display interface connectors configured for various digital display interface standards, including DisplayPort™, High-Definition Multimedia Interface™ (HDMI), video graphics array (VGA), digital visual interface (DVI), low-voltage differential signaling (LVDS), and/or the like. In an embodiment in which card-based processing subsystem 220 is implemented as a network interface card, I/O connectors 321 can include one or more network connection ports.

In the embodiment illustrated in FIGS. 3A and 3B, second rigid PCB 320 is coupled to a backplate bracket 305 that enables card-based processing subsystem 220 to be assembled as part of a server machine, desktop computer, or the like. Thus, second rigid PCB 320 and backplate bracket 305 are disposed on an edge of housing 350 as shown. Backplate bracket 305 couples or mechanically interfaces card-based processing subsystem 220 to a surface of a chassis of a computing device. In some embodiments, card-based processing subsystem 220 can be configured to occupy a region proximate motherboard 206 (shown in FIG. 2) that corresponds to one, two, three, or more chassis expansion slots 205. In such embodiments, backplate bracket 305 and/or second rigid PCB 320 can have a width that occupies a suitable number of chassis expansion slots 205 (e.g., 20 mm, 40 mm, 60 mm, etc.).

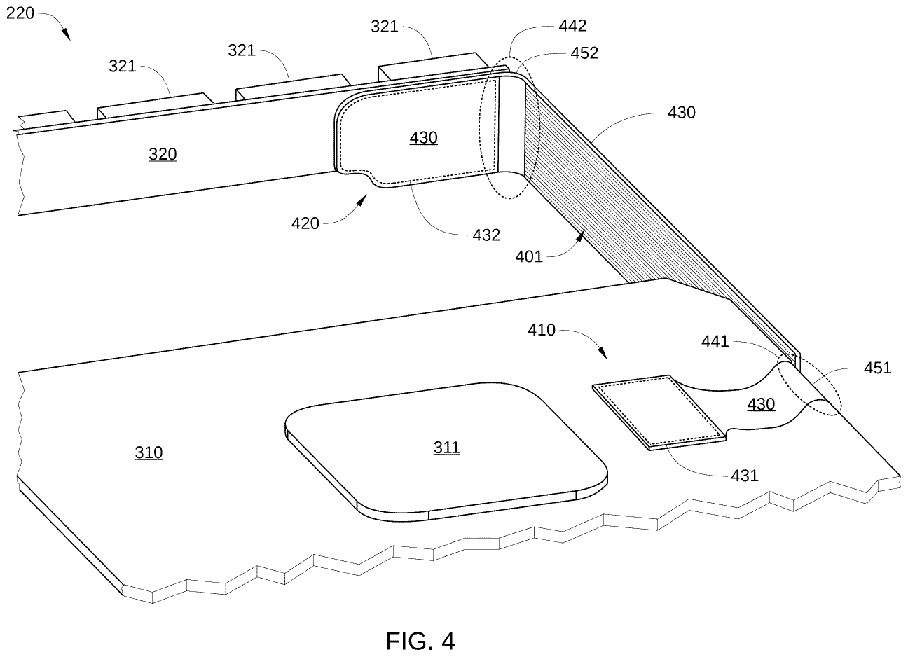

Second rigid PCB 320 is communicatively coupled to first rigid PCB 310 via a flexible PCB (not visible in FIGS. 3A and 3B). Various embodiments of the flexible PCB are described below in conjunction with FIGS. 4-6.

### Small Bending-Radius Flexible PCB

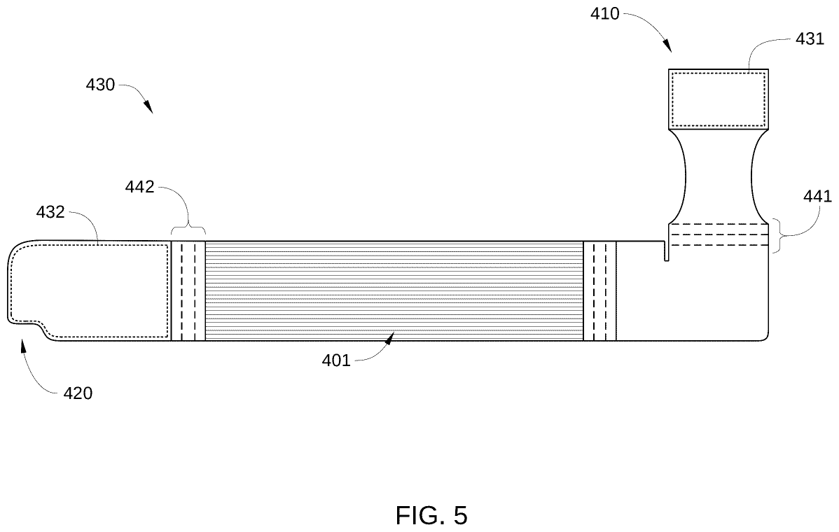

FIG. 4 is a perspective view of a flexible PCB 430, first rigid PCB 310, and second rigid PCB 320 installed within card-based processing subsystem 220, according to various embodiments. For clarity, housing 350, backplate bracket 305, cooling fans 340, and cooling fins 345 have been omitted in FIG. 4. FIG. 5 is a plan view of flexible PCB 430 prior to installation within card-based processing subsystem 220 and in an unbent state.

As shown, flexible PCB 430 communicatively couples first rigid PCB 310 to second rigid PCB 320 by routing a plurality of electrical connections 401 from first rigid PCB 310 to second rigid PCB 320. Electrical connections 401 can include conductive interconnects for various applications, including I/O signals, one or more ground connections, such as ground planes, and/or one or more power connections, such as power planes or power buses. In the embodiment illustrated in FIG. 4, a first end 410 of flexible PCB 430 includes a first connection area 431 (dashed lines) for communicatively coupling to first rigid PCB 310 and a second end that 420 that includes a second connection area 432 (dashed lines) for communicatively coupling to second rigid PCB 320.

Because electrical connections 401 are routed within housing 350 of card-based processing subsystem 220, there is a limited space available for a pathway to route flexible PCB 430 between first rigid PCB 310 and second rigid PCB 320. In addition, first rigid PCB 310 is perpendicular to second rigid PCB 320. As a result, flexible PCB 430 includes one or more bending areas that have a small bending radius. In the embodiment illustrated in FIG. 4, in order to route electrical connections 401 between first rigid PCB 310 and second rigid PCB 320, flexible PCB 430 includes a first bending area 441 and a second bending area 442. First bending area 441 routes electrical connections 401 through a sharp 90 degree bend 451 that positions first connection area 431 onto a suitable region of first rigid PCB 310. Similarly, second bending area 442 routes electrical connections 401 through a sharp 90 degree bend 452 that positions second connection area 432 onto a suitable region of second rigid PCB 320. First connection area 431 can be communicatively coupled to first rigid PCB 310 using any technically feasible board-to-board connectors, such as pins and/or solder balls. Likewise, second connection area 432 can be communicatively coupled to second rigid PCB 320 using similar connectors.

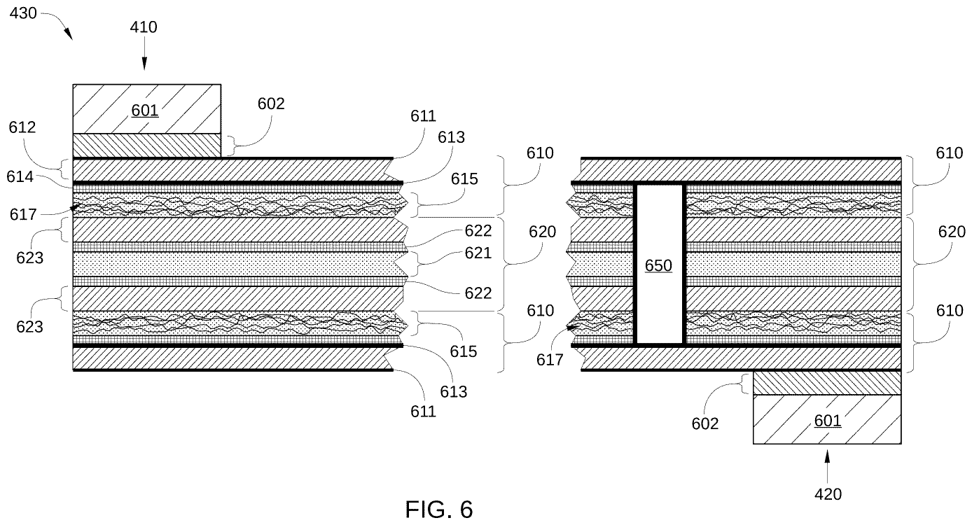

According to various embodiments, first bending area 441 and second bending area 442 of flexible PCB 430 are not compromised by the small radius of 90 degree bend 451 or the small radius of 90 degree bend 452. Specifically, in the embodiments, the inner construction of flexible PCB 430 enables first bending area 441 and second bending area 442 to be bent as shown in FIG. 4 without risk to the continuity of electrical connections 401, dielectric cracking on the outer radius of each bend, or dielectric wrinkling or separation on the inner radius of each bend. One embodiment of the inner construction of flexible PCB 430 is described below in conjunction with FIG. 6.

FIG. 6 is a conceptual illustration of a layer stack-up 600 for flexible PCB 430, according to various embodiments. FIG. 6 provides a cross-sectional view of a plurality of layers included in flexible PCB 430, which are laminated together to form flexible PCB 430. In some embodiments, the plurality of layers include conductive and non-conductive tapes, which extend from first end 410 of flexible PCB 430 to second end 420 of flexible PCB 430. While shown schematically as continuous from first end 410 to second end 420, in some embodiments certain layers within layer stack-up 600, such as certain conductive layers, can be discontinuous and/or patterned as individual interconnect pathways. Generally, layer stack-up 600 includes multiple outer layers 610 of flexible PCB 430 and one or more inner layers 620 of flexible PCB 430.

In the embodiment illustrated in FIG. 6, outer layers 610 include two high-frequency cover layers 611, two cover adhesive layers 612 (one for each high-frequency cover layer 611), two plated conductor layers 613, two metal foil layers 614, and two fiber-reinforced synthetic polymer layers 615. In some embodiments, outer layers 610 are laminated onto inner layers 620 in a symmetrical configuration, in which a corresponding outer layer 610 is formed on each side of inner layers 620, as shown in FIG. 6. Thus, in such embodiments, on each side of flexible PCB 430, layer stack-up 600 includes a high-frequency cover layer 611, a cover adhesive layer 612, a plated conductor layer 613, a metal foil layer 614, and a fiber-reinforced synthetic polymer layer 615. In other embodiments, layer stack-up 600 includes more outer layers 610 or fewer outer layers 610 than shown in FIG. 6. For example, in some embodiments, outer layers 610 include one or more additional metal foil layer 614 and associated fiber-reinforced synthetic polymer layers 615, so that additional electrical connections can be included in flexible PCB 430.

High-frequency cover layers 611 can be a flexible dielectric layer and includes a material selected for high-frequency signals. Adhesive layers 612 are selected to bond an associated high-frequency cover layer 611 to layer stack-up 600. Plated conductor layers 613 can include copper or any other technically feasible electrically conductive plating material, and can be patterned to form various electrical connections within flexible PCB 430. In some embodiments, portions of plated conductor layers 613 can be disposed on surfaces of a via 650 formed within flexible PCB 430, such as a blind via or a buried via. In the embodiment illustrated in FIG. 6, via 650 penetrates all of inner layers 620 and most of outer layers 620, and is electrically coupled to both plated conductor layers 613 and other conductive layers of layer stack-up 600. In other embodiments, via 650 penetrates fewer layers and/or is electrically coupled to selected conductive layers of layer stack-up 600.

Metal foil layers 614 can be patterned to form various electrical connections within flexible PCB 430 to enable the plating of plated conductor layers 613. In some embodiments, each metal foil layer 614 is part of a single metal-clad laminate or tape that also includes a fiber-reinforced synthetic polymer layer 615. For example, in some embodiments, the laminate can be a single-sided flexible copper-clad laminate (FCCL), where the metal foil layer 614 is a layer of copper foil and the fiber-reinforced synthetic polymer layer 615 is a synthetic polymer that is suitable for use in a flexible PCB, such as polyimide. In such embodiments, metal foil layer 614 functions as an electrical conductor (e.g., a signal layer, a ground plane, or a power plane) and fiber-reinforced synthetic polymer layer 615 functions as an electrical insulator.

Fiber-reinforced synthetic polymer layer 615 is a flexible dielectric layer that can be any flexible synthetic polymer suitable for use in a flexible PCB, such as polyimide (PI), polyester (PET), polyethylene nphthalate (PEN), or polytetrafluoroethylene (PTFE), among others. Furthermore, fiber-reinforced synthetic polymer layer 615 includes a plurality of reinforcing fibers 617, such as glass fibers.

In the embodiment illustrated in FIG. 6, inner layers 620 include a synthetic polymer layer 621, two metal foil layers 622, and two adhesive layers 623. In some embodiments, inner layers 620 include more synthetic polymer layers 621, more or fewer metal foil layers 622, and/or more or fewer adhesive layers 623. In such embodiments, the additional metal foil layers 622 may be separated from each other electrically by an additional synthetic polymer layer 621. Synthetic polymer layer 621 is a flexible dielectric layer that functions as an electrical insulator between metal foil layers 622 and serves as a flexible core for flexible PCB 430. Metal foil layers 622 can be consistent with metal foil layers 614. In some embodiments, metal foil layers 622 and synthetic polymer layer 621 are part of a single metal-clad laminate or tape. For example, in some embodiments, the laminate can be a double-sided flexible copper-clad laminate (FCCL), where each metal foil layer 622 is a layer of copper foil and synthetic polymer layer 615 is a synthetic polymer that is suitable for use in a flexible PCB, such as polyimide or PTFE.

According to various embodiments, synthetic polymer layer 615 does not include reinforcing fibers, such as reinforcing fibers 617 in fiber-reinforced synthetic polymer layer 615. As a result, flexible PCB 430 can experience more severe bending without failure of the conductive layers of flexible PCB 430 (e.g., plated conductor layers 613, metal foil layers 614, and/or metal foil layers 622) or of the dielectric layers of flexible PCB 430 (e.g., high-frequency cover layers 611 and/or fiber-reinforced synthetic polymer layers 615).

In some embodiments, flexible PCB 430 further includes a stiffener 601 at first end 410 and/or second end 420, along with an adhesive layer 602 for bonding stiffener 601 to flexible PCB 430. In such embodiments, stiffener 601 facilitates coupling of flexible PCB 430 to a suitable area of a rigid PCB, such as first rigid PCB 310 or second rigid PCB 320 in FIG. 3.

In sum, a flexible PCB is capable of a tighter bend radius than conventional flexible PCBs known in the art. In the embodiments, the flexible PCB includes one or more inner dielectric layers that are disposed within the flexible PCB and one or more outer dielectric layers that enclose the inner dielectric layer(s). In the embodiments, the outer dielectric layers include a synthetic polymer material and reinforcing fibers, while the inner dielectric layer(s) include a synthetic polymer material with no reinforcing fibers.

At least one technical advantage of the disclosed design relative to the prior art is that the disclosed design enables electrical connections to be routed through one or more small-radius turns within a compact computing device without any dielectric cracking or dielectric wrinkling or separation and more effectively than what can be achieved with prior art designs. A further technical advantage is that the disclosed design enables electrical connections to be routed within the compact computing device with low insertion losses and low parasitic impedances, which allows the electrical connections of the disclosed design to transmit high-frequency signals. These technical advantages provide one or more technological advancements over prior art approaches and designs.
1. In some embodiments, a flexible printed circuit board (PCB), includes: a first flexible dielectric layer that includes reinforcing fibers; a second flexible dielectric layer that includes no reinforcing fibers; and a first conductive layer that is disposed between the first dielectric layer and the second dielectric layer and contacts the first dielectric layer and the second dielectric layer.
2. The flexible PCB of clause 1, wherein the first flexible dielectric layer includes a first synthetic polymer material and the second flexible dielectric layer includes a second synthetic polymer material.
3. The flexible PCB of clauses 1 or 2, wherein each of the first synthetic polymer material and the second synthetic polymer material includes polytetrafluoroethylene (PTFE).
4. The flexible PCB of any of clauses 1-3, further comprising a first end that includes a first connection area for communicatively coupling to a first rigid PCB and a second end that includes a second connection area for communicatively coupling to a second rigid PCB.
5. The flexible PCB of any of clauses 1-4, wherein the first connection area includes a first stiffener layer, and the second connection area includes a second stiffener layer.
6. The flexible PCB of any of clauses 1-5, wherein the first stiffener layer is disposed on a first side of the flexible PCB, and the second stiffener layer is disposed on a second side of the flexible PCB that is opposite the first side.
7. The flexible PCB of any of clauses 1-6, further comprising: a third flexible dielectric layer that includes reinforcing fibers; and a second conductive layer that is disposed between the third dielectric layer and the second dielectric layer and contacts the third dielectric layer and the second dielectric layer.
8. The flexible PCB of any of clauses 1-7, wherein the first conductive layer comprises one of a signal layer, a ground plane, or a power plane.
9. The flexible PCB of any of clauses 1-8, further comprising a plurality of plated vias that are formed through the first flexible dielectric layer, the second flexible dielectric layer, and the first conductive layer.
10.The flexible PCB of any of clauses 1-9, wherein the second flexible dielectric layer comprises an inner layer of the flexible PCB.
11.The flexible PCB of any of clauses 1-10, wherein the second flexible dielectric layer comprises a metal-clad laminate layer of the flexible PCB.
12.The flexible PCB of any of clauses 1-11, wherein the first conductive layer is included in the metal-clad laminate layer of the flexible PCB.
13.The flexible PCB of any of clauses 1-12, wherein the first flexible dielectric layer comprises an outer layer of the flexible PCB.
14.In some embodiments, a card-based processing subsystem, includes: a housing; a processor mounted on a first rigid printed circuit board (PCB) that is disposed within the housing; a second rigid PCB that is communicatively coupled to the first rigid PCB via a flexible PCB; and the flexible PCB, wherein the flexible PCB includes: a first flexible dielectric layer that includes reinforcing fibers; a second flexible dielectric layer that includes no reinforcing fibers; and a first conductive layer that is disposed between the first dielectric layer and the second dielectric layer and contacts the first dielectric layer and the second dielectric layer.
15.The card-based processing subsystem of clause 14, wherein the second rigid PCB is disposed on an edge of the housing.
16.The card-based processing subsystem of clauses 14 or 15, wherein the second rigid PCB has one or more digital display interface connectors mounted thereon.
17.The card-based processing subsystem of any of clauses 14-16, wherein the first rigid PCB is perpendicular to the second rigid PCB.
18.The card-based processing subsystem of any of clauses 14-17, wherein the second flexible dielectric layer comprises an inner layer of the flexible PCB.
19.The card-based processing subsystem of any of clauses 14-18, wherein the second flexible dielectric layer comprises a metal-clad laminate layer of the flexible PCB.
20.The card-based processing subsystem of any of clauses 14-19, wherein the first flexible dielectric layer comprises an outer layer of the flexible PCB.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. A flexible printed circuit board (PCB), comprising:
a first flexible dielectric layer that includes reinforcing fibers;
a second flexible dielectric layer that includes no reinforcing fibers; and
a first conductive layer that is disposed between the first dielectric layer and the second dielectric layer and contacts the first dielectric layer and the second dielectric layer.

2. The flexible PCB of claim 1, wherein the first flexible dielectric layer includes a first synthetic polymer material and the second flexible dielectric layer includes a second synthetic polymer material.

3. The flexible PCB of claim 2, wherein each of the first synthetic polymer material and the second synthetic polymer material includes polytetrafluoroethylene (PTFE).

4. The flexible PCB of claim 1, further comprising a first end that includes a first connection area for communicatively coupling to a first rigid PCB and a second end that includes a second connection area for communicatively coupling to a second rigid PCB.

5. The flexible PCB of claim 1, wherein the first connection area includes a first stiffener layer, and the second connection area includes a second stiffener layer.

6. The flexible PCB of claim 5, wherein the first stiffener layer is disposed on a first side of the flexible PCB, and the second stiffener layer is disposed on a second side of the flexible PCB that is opposite the first side.

7. The flexible PCB of claim 1, further comprising:
a third flexible dielectric layer that includes reinforcing fibers; and
a second conductive layer that is disposed between the third dielectric layer and the second dielectric layer and contacts the third dielectric layer and the second dielectric layer.

8. The flexible PCB of claim 1, wherein the first conductive layer comprises one of a signal layer, a ground plane, or a power plane.

9. The flexible PCB of claim 1, further comprising a plurality of plated vias that are formed through the first flexible dielectric layer, the second flexible dielectric layer, and the first conductive layer.

10. The flexible PCB of claim 1, wherein the second flexible dielectric layer comprises an inner layer of the flexible PCB.

11. The flexible PCB of claim 1, wherein the second flexible dielectric layer comprises a metal-clad laminate layer of the flexible PCB.

12. The flexible PCB of claim 1, wherein the first conductive layer is included in the metal-clad laminate layer of the flexible PCB.

13. The flexible PCB of claim 1, wherein the first flexible dielectric layer comprises an outer layer of the flexible PCB.

14. A card-based processing subsystem, comprising:
a housing;
a processor mounted on a first rigid printed circuit board (PCB) that is disposed within the housing;
a second rigid PCB that is communicatively coupled to the first rigid PCB via a flexible PCB; and
the flexible PCB, wherein the flexible PCB includes:
a first flexible dielectric layer that includes reinforcing fibers;
a second flexible dielectric layer that includes no reinforcing fibers; and
a first conductive layer that is disposed between the first dielectric layer and the second dielectric layer and contacts the first dielectric layer and the second dielectric layer.

15. The card-based processing subsystem of claim 14, wherein the second rigid PCB is disposed on an edge of the housing.

16. The card-based processing subsystem of claim 14, wherein the second rigid PCB has one or more digital display interface connectors mounted thereon.

17. The card-based processing subsystem of claim 14, wherein the first rigid PCB is perpendicular to the second rigid PCB.

18. The card-based processing subsystem of claim 14, wherein the second flexible dielectric layer comprises an inner layer of the flexible PCB.

19. The card-based processing subsystem of claim 14, wherein the second flexible dielectric layer comprises a metal-clad laminate layer of the flexible PCB.

20. The card-based processing subsystem of claim 14, wherein the first flexible dielectric layer comprises an outer layer of the flexible PCB.
